(19) United States
(12) Patent Application Publication
(10) Pub. No.: US 2026/0076126 A1
(43) Pub. Date: Mar. 12, 2026

(54) SEMICONDUCTOR STRUCTURE AND MANUFACTURING METHOD OF SEMICONDUCTOR STRUCTURE

(71) Applicant: Taiwan Semiconductor Manufacturing Company, Ltd., Hsinchu (TW)

(72) Inventors: Chien-Hsun Lin, Kaohsiung City (TW); Chih-Hsiang Yao, Hsinchu (TW)

(73) Assignee: Taiwan Semiconductor Manufacturing Company, Ltd., Hsinchu (TW)

(21) Appl. No.: 18/827,819

(22) Filed: Sep. 8, 2024

(51) Int. Cl. H01L 21/78; H01L 21/66; H01L 23/58; H01L 29/06; H01L 29/66

(52) U.S. Cl. CPC H10P 54/00; H10D 30/014; H10D 62/121; H10D 64/017; H10P 74/277; H10W 42/00

(57) ABSTRACT

A semiconductor structure and a manufacturing method of a semiconductor structure are provided. The semiconductor structure includes a scribe line region. The scribe line region includes a test region and a dicing region adjacent to the test region. The test region includes an active element. The dicing region includes at least one layer having a plurality of patterns.

### BACKGROUND

A scribe line region is a region of a wafer that is removed during a singulation process that separates the wafer into a plurality of dies. The scribe line region usually includes a test region where test elements are formed to facilitate process monitoring, dimensional inspection, and/or electrical testing. When the selected dicing approach is not suitable for metal removal, the scribe line region needs to further reserve an “all-empty” region (also known as a metal-free region or a pattern-free region) to facilitate dicing. However, the huge pattern density difference between the test region and the all-empty region leads to over-polishing or dishing of the all-empty region during a chemical mechanical polishing (CMP) process, which impacts topography of adjacent test patterns, leading to abnormal inline data and/or electrical wafer acceptance test (WAT) performance, and even affecting chip yield.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of a semiconductor structure according to some embodiments of the present disclosure.

FIG. 2 is an enlarged view of a region R in FIG. 1.

FIG. 3 to FIG. 13 are schematic views illustrating a manufacturing method of a semiconductor structure according to some embodiments of the present disclosure.

FIG. 14 to FIG. 29 are schematic views illustrating a manufacturing method of another semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Plasma dicing is an emerging technology that uses chemical dry etching with plasma process to singulate an entire wafer at once. In other words, plasma dicing removes materials in the dicing lane (or dicing region) chemically, which offers the advantages of higher die strength and faster throughput compared to other wafer dicing approaches (blade or laser). However, the plasma dry etching technology is incompatible with metal. Specifically, plasma dicing is highly selective etching to silicon, but can easily cause wafer arcing during metal removal, leading to defects, yield loss and reliability failures. Therefore, current plasma dicing lane is “all-empty”, meaning there is no metal (and therefore the dielectric layer has no pattern in the plasma dicing lane) in to facilitate plasma dicing. The plasma dicing region is located between a seal ring surrounding the chip region and a test region where inline and electrical test patterns are located. Since a removal rate of a chemical mechanical polishing process decreases with increasing pattern density, a huge pattern density difference between the plasma dicing region (“all-empty” region) and the adjacent region (e.g., the test region) can cause over-polishing or dishing of the all-empty region during chemical mechanical polishing processes, which impacts topography of adjacent test patterns, leading to abnormal inline data and/or electrical WAT performance, and even affecting chip yield.

In the present disclosure, at least one layer (e.g., an insulator layer, an epitaxial layer and/or a dielectric layer) is patterned to form a plurality of patterns in the dicing region to reduce the pattern density difference between the dicing region and the test region, and therefore improve surface topography obtained by the CMP process, mitigate impact on abnormal performance of inline and electrical test patterns, and/or mitigate device electrical performance deviation. During the manufacturing process of the semiconductor structure, a dummy gate (e.g., made of polysilicon) can be formed in the dicing region, and then the dummy gate can be replaced with a replacement dielectric pattern instead of a metal gate to avoid wafer arcing defects caused by plasma dicing to the metal gate. Alternatively, after the dummy gate is replaced with the metal gate, the metal gate in the dicing region can then be replaced with a replacement dielectric pattern to avoid wafer arcing defects caused by plasma dicing to the metal gate. The manufacturing process of the semiconductor structure according to some embodiments of the present disclosure is compatible with the manufacturing process of the current semiconductor structure, and additional processes are not needed. In some embodiments, the epitaxial layer has balanced N type and P type epitaxial regions (N type epitaxial pattern density is close to or the same as P type epitaxial pattern density) to avoid abnormal epitaxial volume.

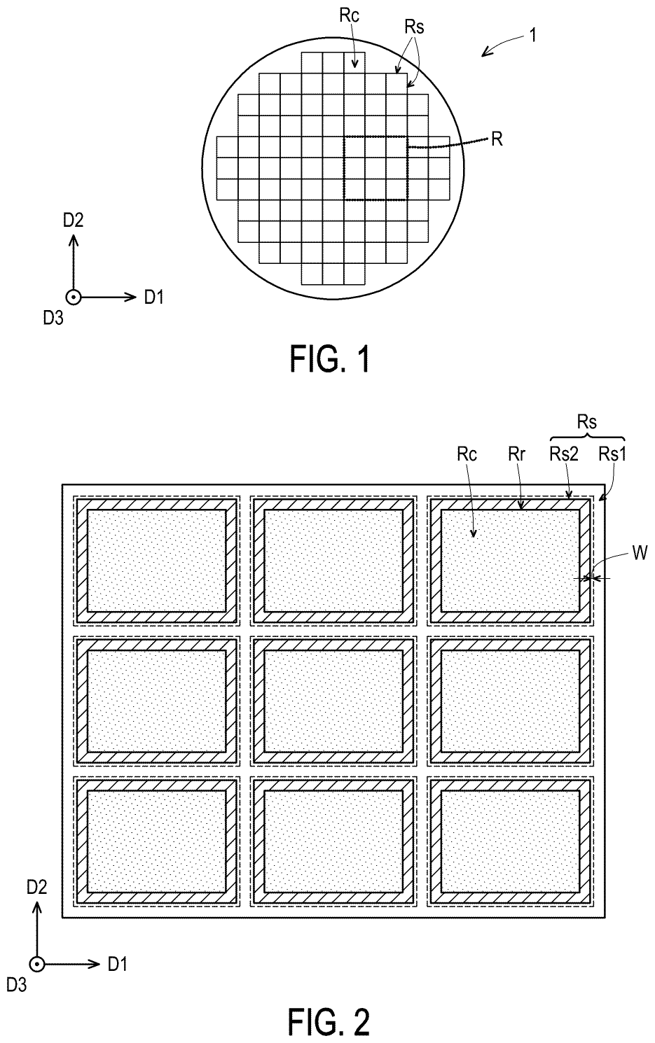

FIG. 1 is a schematic top view of a semiconductor structure according to some embodiments of the present disclosure. FIG. 2 is an enlarged view of a region R in FIG. 1. Referring to FIG. 1 and FIG. 2, a semiconductor structure 1 according to some embodiments of the present disclosure is provided. The semiconductor structure 1 is, for example, a structure (e.g., a wafer-form structure, but not limited thereto) that can be separated into a plurality of dies through a dicing process (or a singulation process). Specifically, the semiconductor structure 1 includes a scribe line region Rs on which the dicing process (or a singulation process) is performed to separate the semiconductor structure 1 into a plurality of dies.

The semiconductor structure 1 also includes a chip region Rc surrounded by the scribe line region Rs. The chip region Rc includes, for example, at least one electronic element, such as at least one active element, at least one passive element, or a combination thereof, but not limited thereto. The chip region Rc includes, for example, a plurality of wirings and a plurality of vias, but not limited thereto.

In some embodiments, as shown in FIG. 2, the semiconductor structure 1 can further include a seal ring region Rr between the chip region Rc and the scribe line region Rs to protect the chip region Rc from being damaged or impacted by the singulation process, external dust and/or static electricity, etc. The seal ring region Rr may include at least one electronic element, a plurality of wirings and a plurality of vias, but not limited thereto.

As shown in FIG. 2, the scribe line region Rs includes, for example, a test region Rs1 and a dicing region Rs2 adjacent to (e.g., next to) the test region Rs1. For example, the dicing region Rs2 is between the chip region Rc and the test region Rs1. In embodiments where there is a seal ring region Rr, the dicing region Rs2 is between the seal ring region Rr and the test region Rs1.

The test region Rs1 includes, for example, at least one test element (such as an active element) that is formed to facilitate process monitoring, dimensional inspection, and/or electrical testing. Specifically, the test region Rs1 may include at least one electronic element (such as an active element) that is manufactured at the same time as the electronic element in the chip region Rc, and the at least one electronic element (such as an active element) may have the same or similar critical dimension and construction as the electronic element in the chip region Rc. In this way, the process status in the chip region Rc can be confirmed by monitoring the process in the test region Rs1, and the status of the electronic element in the chip region Rc (such as whether the size meets the specifications and electrical performance, etc.) can be confirmed by performing dimensional inspection and electrical testing on the electronic element in the test region Rs1.

The dicing region Rs2 is a region of the scribe line region Rs that will be removed in a dicing process (or a singulation process). In some embodiments, a width W of the dicing region Rs2 is approximately 10 μm, but not limited thereto. The dicing region Rs2 can include at least one layer that is also included in other regions, such as the chip region Rc, the seal ring region Rr and/or the test region Rs1 mentioned above. For example, in embodiments where the semiconductor structure 1 is singulated by a plasma dicing approach, the dicing region Rs2 is a metal-free region and includes an insulator layer, an epitaxial layer and/or a dielectric layer that is/are also included in other regions, such as the chip region Rc, the seal ring region Rr and/or the test region Rs1 mentioned above. In addition, the at least one layer can be patterned to include a plurality of patterns in the dicing region Rs2 to reduce the pattern density difference between the dicing region and the adjacent region (e.g., the test region Rs1).

In some embodiments, in each one of the at least one layer mentioned above, a plurality of patterns that follow the design rules can be formed in both of the dicing region Rs2 and the test region Rs1, wherein the patterns in the dicing region Rs2 are similar to or the same as the neighboring test patterns in the test region Rs1, so that the at least one layer has a similar or the same pattern density in the dicing region Rs2 and the test region Rs1. For example, a layer included in the dicing region Rs2 and the test region Rs1 can have a pattern density d1 in the test region Rs1 and a pattern density d2 in the dicing region Rs2. The layer has the same pattern density in the dicing region Rs2 and the test region Rs1 refers to d1=d2. The layer has a similar pattern density in the dicing region Rs2 and the test region Rs1 refers to 0.5*d1≤d2≤1.5*d1, but not limited thereto.

In some embodiments, the semiconductor structure 1 includes a plurality of chip regions Rc, a plurality of seal ring regions Rr and a plurality of dicing regions Rs2. The plurality of chip regions Rc may be arranged in an array along a first direction D1 and a second direction D2. The first direction D1 and the second direction D2 are perpendicular to a thickness direction (e.g., a third direction D3) of the semiconductor structure 1. The first direction D1 is intersected with the second direction D2 and is, for example, perpendicular to the second direction D2, but not limited thereto. The plurality of seal ring regions Rr surround the plurality of chip regions Rc, respectively. The plurality of dicing regions Rs2 surround the plurality of seal ring regions Rr, respectively. The test region Rs1 may be a grid-shape region, and the plurality of dicing regions Rs2 may be separated by the test region Rs1. After the semiconductor structure 1 undergoes a dicing process (or a singulation process), the plurality of dicing regions Rs2 are removed, and a plurality of dies are formed, wherein each of the die may include one chip region Rc and one seal ring region Rr surrounding the chip region Rc.

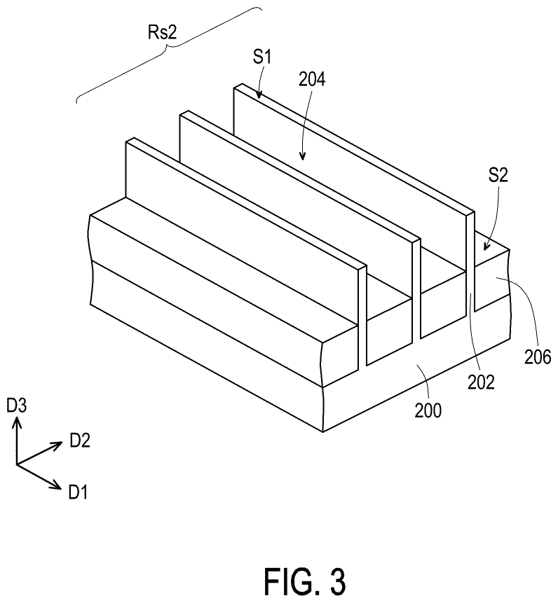

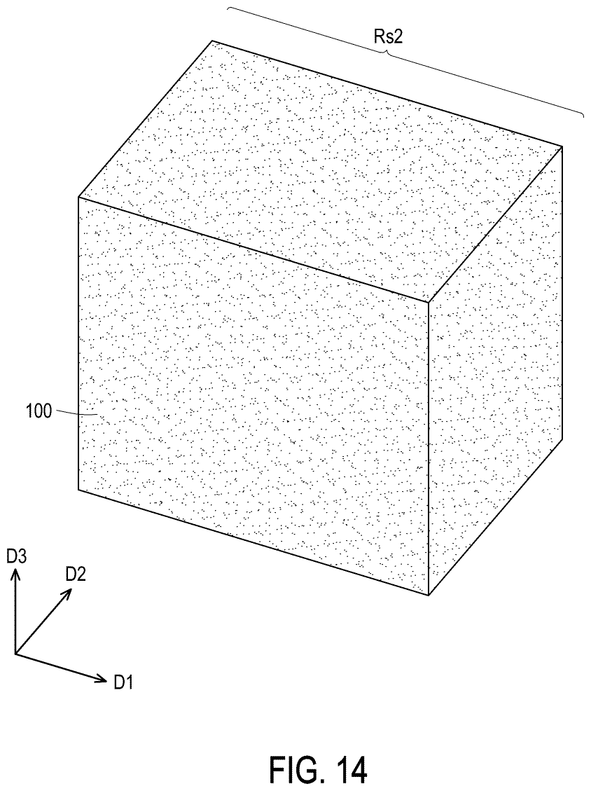

In some embodiments, a manufacturing method of the semiconductor structure 1 includes forming an active element in a test region (e.g., the test region Rs1) of a scribe line region (e.g., the scribe line region Rs); and forming at least one layer having a plurality of patterns in a dicing region (e.g., the dicing region Rs2) of the scribe line region, wherein the dicing region is adjacent to the test region. FIG. 3 to FIG. 13 and FIG. 14 to FIG. 29 are provided to show two kinds of semiconductor structures and manufacturing methods thereof, wherein FIG. 3 to FIG. 13 are schematic views illustrating a manufacturing method of a semiconductor structure according to some embodiments of the present disclosure, and FIG. 14 to FIG. 29 are schematic views illustrating a manufacturing method of another semiconductor structure according to some embodiments of the present disclosure. However, it should be understood that FIG. 3 to FIG. 29 are only examples, and the semiconductor structure and manufacturing method thereof of the present disclosure are not limited to those shown in FIG. 3 to FIG. 29.

FIG. 3 is a perspective view illustrating one of various stages of a method of fabricating a semiconductor structure in accordance with some embodiments of the disclosure. Referring to FIG. 3, a substrate 200 is provided in a chamber (not shown). In some embodiments, the substrate 200 may be placed in the desired chamber based on the sequential processes. The substrate 200 includes at least one protrusion pattern (e.g., a fin 202) thereon. In some embodiments, the substrate 200 may have a plurality of fins 202. The plurality of fins 202 may extend along the first direction D1 and be arranged along the second direction D2. The substrate 200 may also include a plurality of trenches 204 therein. Each trench 204 is located between two adjacent fins 202. In some embodiments, the substrate 200 may be a bulk semiconductor substrate, an SOI substrate, or the like. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate, may also be used.

In some embodiments, an insulator layer including a plurality of insulators 206 is formed or disposed on the substrate 200. In some embodiments, the insulators 206 may be referred to as “Shallow Trench Isolation (STI)”, and the plurality of patterns (e.g., the plurality of insulators 206) of the insulator layer include a plurality of shallow trench isolation patterns. The plurality of insulators 206 are formed in the plurality of trenches 204. The plurality of insulators 206 may extend along the first direction D1 and be arranged along the second direction D2. The plurality of shallow trench isolation patterns (the plurality of insulators 206) are separated by the plurality of protrusion patterns (fins 202). For example, each fin 202 is sandwiched between two adjacent insulators 206. In some embodiments, top surfaces S2 of the insulators 206 are lower than top surfaces S1 of the fins 202. For example, the fins 202 protrude from the top surfaces S2 of the insulators 206. In some embodiments, the top surfaces S2 of the insulators 206 may have a flat surface (as shown in FIG. 3), a convex surface, a concave surface, or a combination thereof.

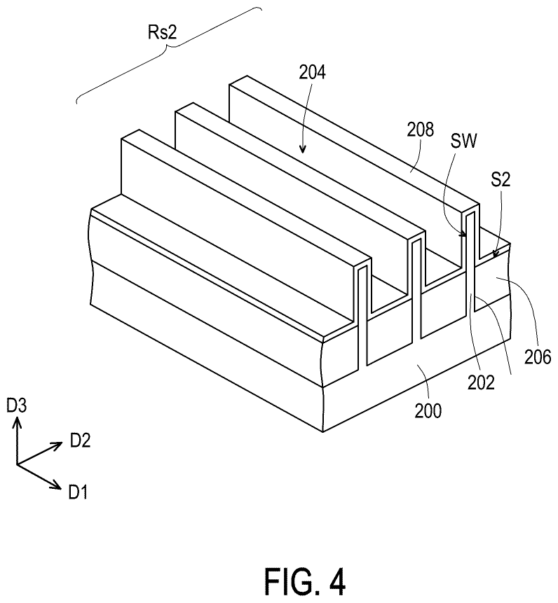

FIG. 4 is a perspective view illustrating one of various stages of a method of fabricating the semiconductor structure in accordance with some embodiments of the disclosure. Referring to FIG. 4, a dielectric layer 208 is formed on the fins 202. In some embodiments, the dielectric layer 208 may be further disposed on the insulators 206. In some embodiments, a portion of the dielectric layer 208 on the top surfaces S1 of the fins 202 may be integrally formed with a portion of the dielectric layer 208 on sidewalls SW of the fins 202. That is, the dielectric layer 208 continuously covers the fins 202. In some embodiments, a thickness of the dielectric layer 208 on the top surfaces S1 of the fins 202 may be substantially the same as the thickness of the dielectric layer 208 on the sidewalls SW of the fins 202. In some embodiments, the material of the dielectric layer 208 may be silicon oxide, silicon nitride, silicon carbonitride or the like. In some embodiments, the method of forming the dielectric layer 208 may be an Atomic Layer Deposition (ALD) method.

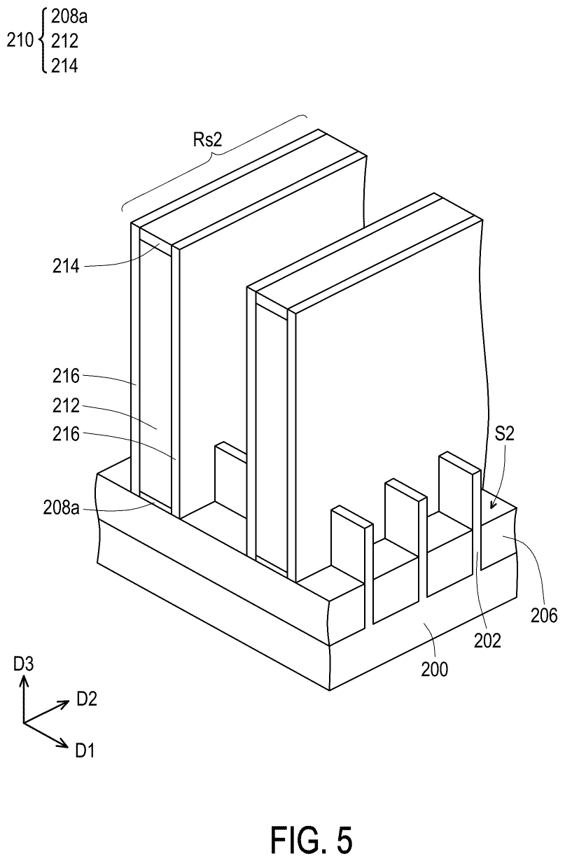

FIG. 5 is a perspective view illustrating one of various stages of a method of fabricating the semiconductor structure in accordance with some embodiments of the disclosure. Referring to FIG. 5, a plurality of dummy gate structures 210 is formed over a portion of the fins 202 and a portion of the insulators 206. In some embodiments, the dummy gate structures 210 are formed across the fins 202. For example, an extending direction (e.g., the second direction D2) of the dummy gate structures 210 may be perpendicular to an extending direction (e.g., the first direction D1) of the fins 202. In some embodiments, each dummy gate structure 210 may include a dielectric structure 208a, a dummy gate 212 disposed over the dielectric structure 208a, and a mask layer 214 disposed over the dummy gate 212. In some embodiments, before forming the dummy gate 212, a portion of the dielectric layer 208 (see FIG. 4) is removed to form the dielectric structure 208a, and a portion of the fins 202 is exposed by the dielectric structure 208a.

Then, as illustrated in FIG. 5, the dummy gate 212 is formed on the dielectric structure 208a. The dielectric structure 208 may be used to separate the fins 202 and the dummy gate 212. In some embodiments, the dummy gate 212 may be a single-layered structure or a multi-layered structure. In some embodiments, the dummy gate 212 includes a silicon-containing material, such as polysilicon, amorphous silicon, or a combination thereof. The dummy gate 212 may be formed by a suitable process, such as ALD, Chemical Vapor Deposition (CVD), Physical Vapor Deposition (PVD), plating, or a combination thereof. In some embodiments, the mask layer 214 is then formed on the dummy gate 212. In some embodiments, the mask layer 214 may be formed of silicon nitride, silicon oxide, silicon carbonitride, combinations thereof, or the like.

In addition to the dummy gate structures 210, multiple pairs of spacers 216 are also formed over portions of the fins 202 and portions of the insulators 206. As illustrated in FIG. 5, the spacers 216 are disposed on sidewalls of the dummy gate structures 210. For example, the dielectric structure 208a, the dummy gate 212, and the mask layer 214 are sandwiched between a pair of spacers 216. In some embodiments, the spacers 216 and the dummy gate structures 210 may have the same extending direction (e.g., the second direction D2). In some embodiments, the spacers 216 may be formed of dielectric materials, such as silicon oxide, silicon nitride, silicon carbonitride, SiCON, or a combination thereof. In some embodiments, the spacers 216 may be formed by a thermal oxidation or a deposition followed by an anisotropic etch. It should be noted that the spacers 216 may be a single-layered structure or a multi-layered structure.

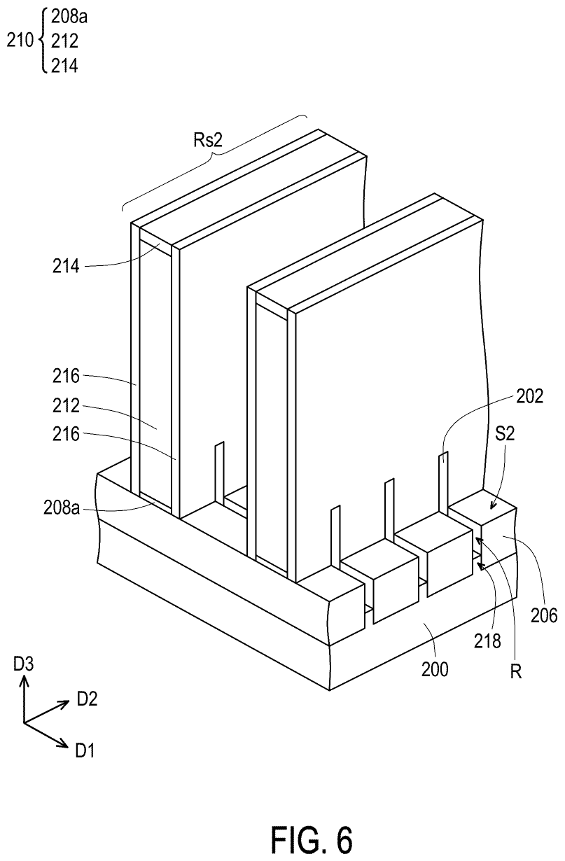

FIG. 6 is a perspective view illustrating one of various stages of a method of fabricating the semiconductor structure in accordance with some embodiments of the disclosure. Referring to FIG. 6, the fins 202 exposed by the dummy gate structure 210 and the spacers 216 are removed/recessed to form a plurality of recessed portions R. Portions of the fins 202 may be removed by, for example, anisotropic etching, isotropic etching, or a combination thereof. In some embodiments, portions of the fins 202 are recessed below the top surfaces S2 of the insulators 206. In some embodiments, a depth of the recessed portions R is less than a thickness of the insulators 206. In other words, the fins 202 exposed by the dummy gate structure 210 and the spacers 216 are not entirely removed, and the remaining fins 202 located in the recessed portion R form source/drain regions 218 of the fins 202. As illustrated in FIG. 6, the fins 202 covered by the dummy gate structure 210 and the spacers 216 are not etched and are exposed by sidewalls of the spacers 216.

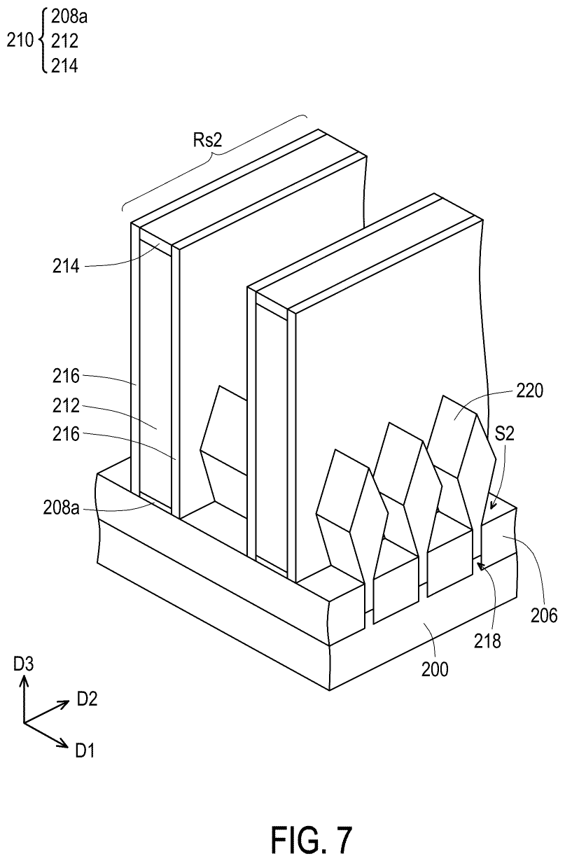

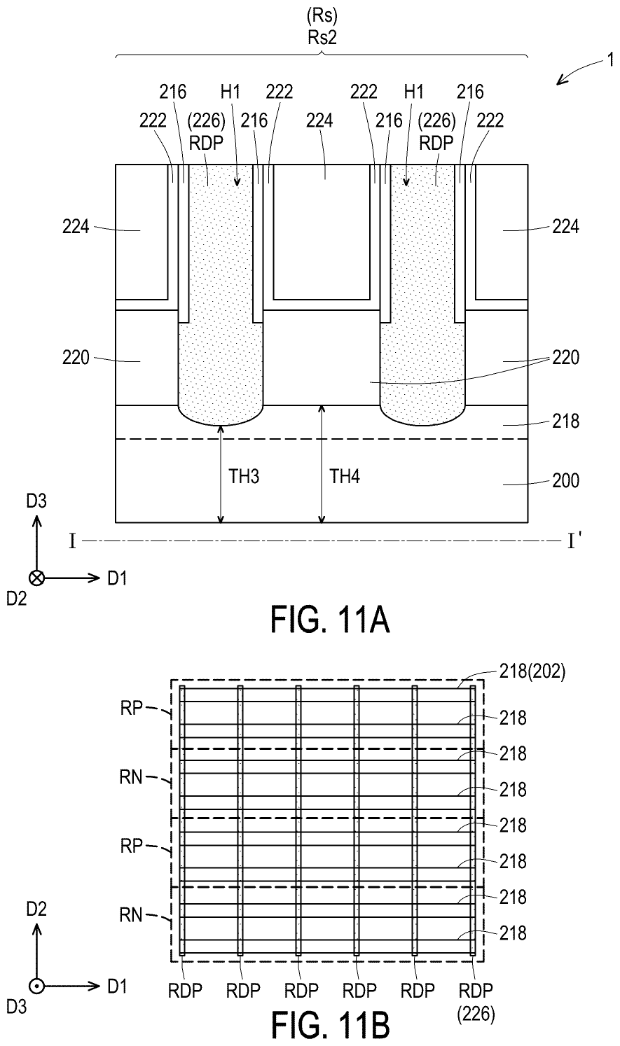

FIG. 7 is a perspective view illustrating one of various stages of a method of fabricating the semiconductor structure in accordance with some embodiments of the disclosure. Referring to FIG. 7, an epitaxial layer including a plurality of strained material structures 220 (or a highly doped low resistance material structure) is grown over the recessed portions R of the fins 202 and extends beyond the top surfaces S2 of the insulators 206. That is, the strained material structures 220 may be formed over portions of the fins 202 revealed by the dummy gate structure 210 and the spacers 216; alternatively speaking, the plurality of strained material structures 220 protrude out of gaps (e.g., the plurality of recessed portions R) between the plurality of shallow trench isolation patterns (e.g., the plurality of insulators 206). In some embodiments, the strained material structures 220 are formed over the source/drain regions 218 of the fins 202 to function as sources/drains of the subsequently formed device/element. In some embodiments, the strained material structures 220 may be doped with a conductive dopant. In some embodiments, the strained material structures 220, such as SiGe, SiGeB, Ge, GeSn, SiC, SiP, SiCP, a combination of SiC/SiP, or the like, are epitaxial-grown with dopants. In some alternative embodiments, the strained material structures 220 may also include III-V compound semiconductors, such as GaAs, InP, GaN, InGaAs, InAlAs, GaSb, AlSb, AlAs, AlP, GaP, or a combination thereof. It should be noted that the recess step illustrated in FIG. 6 may be omitted in some embodiments. For example, the strained material structures 220 may be formed on the un-recessed fins 202. That is, the strained material structures 220 may be formed on the source/drain regions 218 of the un-recessed fins 202. In some embodiments, the epitaxial layer has balanced N type and P type epitaxial regions to avoid abnormal epitaxial volume. As shown in FIG. 11B, the N type epitaxial regions RN and the P type epitaxial regions RP may be alternately arranged along the second direction D2, and the N type epitaxial regions RN and the P type epitaxial regions RP may have similar or the same width along the second direction D2 so that N type epitaxial pattern density is close to or the same as P type epitaxial pattern density. In some embodiments, widths of the N type and P type epitaxial regions are 100 nm or more to avoid peeling of the photoresist layer fabricated for the doping process.

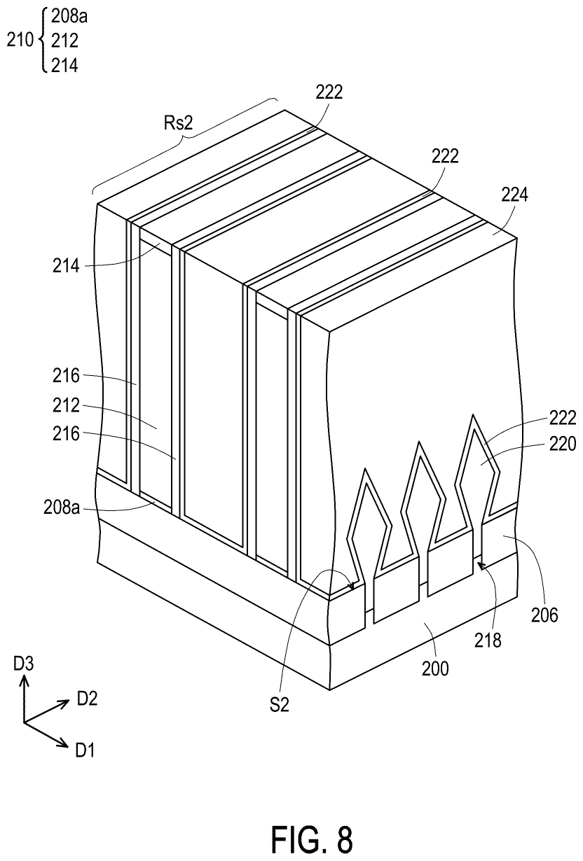

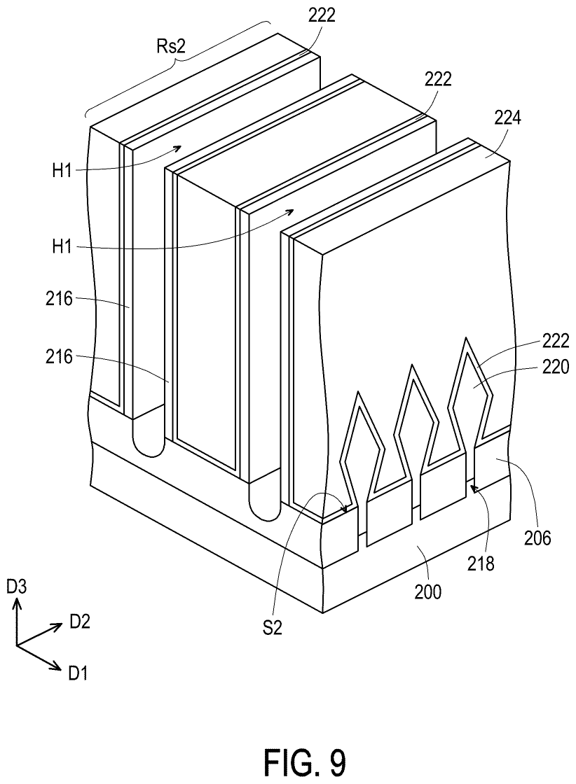

FIG. 8 is a perspective view illustrating one of various stages of a method of fabricating the semiconductor structure in accordance with some embodiments of the disclosure. Referring to FIG. 8, an etch stop layer 222 and an interlayer dielectric layer 224 are sequentially formed over the strained material structures 220 and the insulators 206. In some embodiments, the etch stop layer 222 is formed adjacent to the spacers 216. As illustrated in FIG. 8, the etch stop layer 222 is formed on the top surfaces S2 of the insulators 206 and the strained material structures 220. In some embodiments, the etch stop layer 222 may be formed of silicon oxide, silicon nitride, silicon carbo-nitride, or the like. In some embodiments, the etch stop layer 222 may be formed through, for example, CVD, Sub Atmospheric Chemical Vapor Deposition (SACVD), Molecular Layer Deposition (MLD), ALD, or the like. In some embodiments, the etch stop layer 222 may be referred to as “contact etch stop layer (CESL).”

As illustrated in FIG. 8, the interlayer dielectric layer 224 is formed on the etch stop layer 222. In some embodiments, a material of the interlayer dielectric layer 224 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some alternative embodiments, the material of the interlayer dielectric layer 224 includes low-k dielectric materials. It is understood that the interlayer dielectric layer 224 may include one or more dielectric materials and/or one or more dielectric layers. In some embodiments, the interlayer dielectric layer 224 is formed to a suitable thickness by Flowable Chemical Vapor Deposition (FCVD), CVD, High Density Plasma Chemical Vapor Deposition (HDPCVD), SACVD, spin-on, sputtering, or other suitable methods. For example, an interlayer dielectric material layer (not shown) may be formed to cover the etch stop layer 222, the dummy gate structures 210, and the spacers 216. Subsequently, the thickness of the interlayer dielectric material layer is reduced until a top surface of the dummy gate structure 210 is exposed, so as to form the interlayer dielectric layer 224. The reduction in thickness of the interlayer dielectric material layer may be achieved by a chemical mechanical polishing (CMP) process, an etching process, or other suitable processes. After reducing the thickness of the interlayer dielectric material layer, top surfaces of the dummy gate structures 210, top surfaces of the spacers 216, a top surface of the etch stop layer 222, and a top surface of the interlayer dielectric layer 224 are substantially coplanar.

FIG. 9 is a perspective view illustrating one of various stages of a method of fabricating the semiconductor structure in accordance with some embodiments of the disclosure. Referring to FIG. 8 and FIG. 9, the mask layers 214 and the dummy gates 212 are removed to form hollow portions H1 between two adjacent spacers 216. In some embodiments, the dielectric structures 208a, a portion of the insulators 206 below the dielectric structures 208a and at least a portion of the fins 202 (see FIG. 6) overlapped with the dummy gate structures 210 may be removed simultaneously.

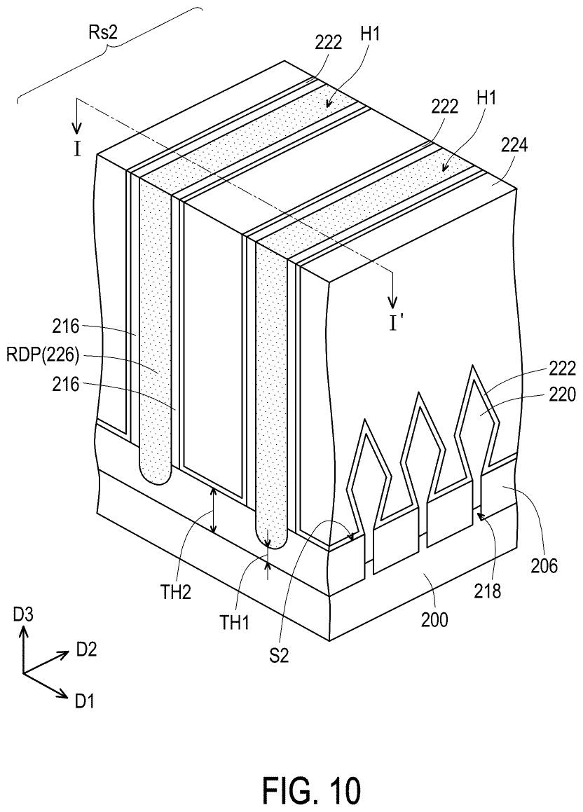

FIG. 10 is a perspective view illustrating one of various stages of a method of fabricating the semiconductor structure in accordance with some embodiments of the disclosure. FIG. 11A is a cross-sectional view taken along line I-I′ of FIG. 10. FIG. 11B is a top view of a plurality of replacement dielectric patterns RDP and the plurality of source/drain regions 218.

Referring to 10 and FIG. 11A, a dielectric layer 226 is formed into the hollow portions H1 to form a plurality of replacement dielectric patterns RDP disposed on the plurality of shallow trench isolation patterns (the plurality of insulators 206). For example, each replacement dielectric pattern RDP is located in a corresponding hollow portion H1 and is sandwiched between two adjacent spacers 216 in the dicing region RS2, wherein an extension direction (e.g., the second direction D2) of the plurality of replacement dielectric patterns is intersected with an extension direction (e.g., the first direction D1) of the plurality of shallow trench isolation patterns (the plurality of insulators 206). In some embodiments, the material of the dielectric layer 226 may be identical to or different from the material of the dielectric layer 208. For example, the material of the dielectric layer 226 includes silicon oxide, silicon nitride, silicon oxynitride, or a combination thereof. In some alternative embodiments, the dielectric layer 226 is made of a high-k dielectric material. In some embodiments, the dielectric layer 226 may be formed by, for example, Molecular-Beam Deposition (MBD), ALD, PECVD, thermal oxidation, UV-ozone oxidation, a combination thereof, or the like.

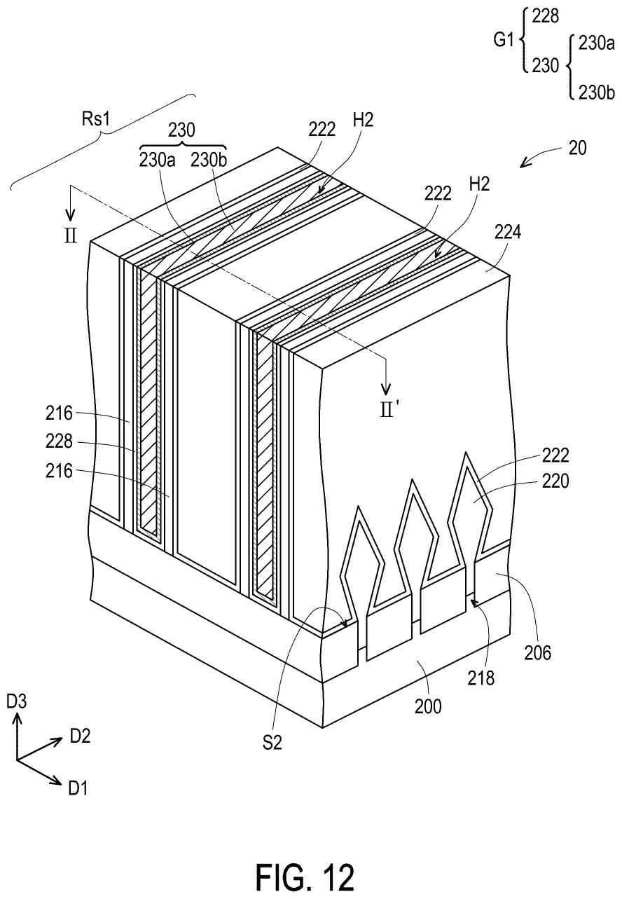

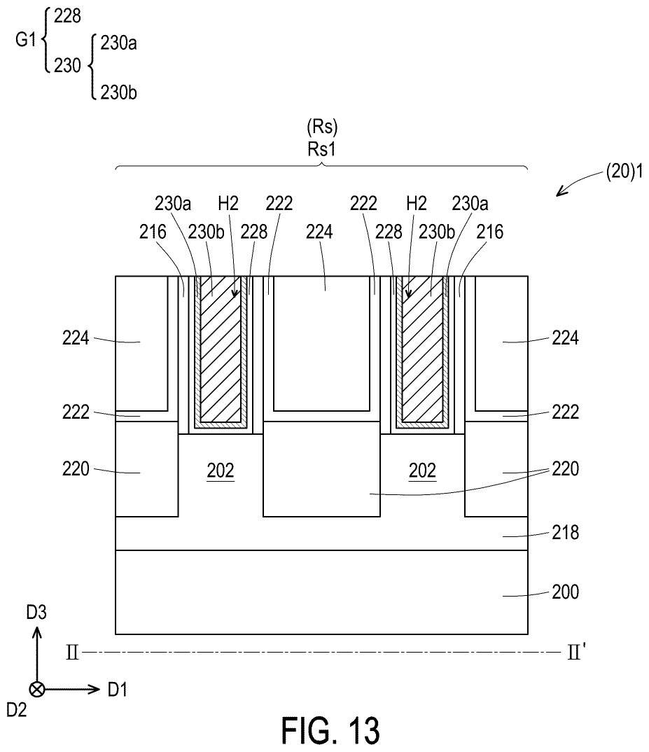

FIG. 12 is a perspective view illustrating one of various stages of a method of fabricating the semiconductor structure in accordance with some embodiments of the disclosure. FIG. 13 is a cross-sectional view taken along line II-II′ of FIG. 12. Referring to FIG. 12 and FIG. 13, an active device 20 is formed in the test region Rs1. The active device 20 is, for example, a fin field-effect transistor, but not limited thereto. In some alternative elements, the active device 20 can be a nanowire field-effect transistor or a nanosheet field-effect transistor.

As shown in FIG. 12 and FIG. 13, the test region Rs1 also includes the substrate 200, the plurality of fins 202, the plurality of strained material structures 220, the spacers 216, the etch stop layer 222 and the interlayer dielectric layer 224, and the above-mentioned elements or layers can be fabricated in the steps shown in FIG. 3 to FIG. 8. At least one of the above-mentioned layers can have the same or similar patten density in the test region Rs1 and the dicing region Rs2. For example, the insulator layer including the plurality of insulators 206 (or the epitaxial layer including the plurality of strained material structures 220) can have a pattern density d1 in the test region Rs1 and a pattern density d2 in the dicing region Rs2, d1 may be equal to or approximately to d2, and both d1 and d2 follow the design rules.

In some embodiments, when the mask layers 214 and the dummy gates 212 in the dicing region Rs2 are removed to form hollow portions H1 between two adjacent spacers 216 (as shown in FIG. 9), a photoresist layer (not shown) is formed in the test region Rs1 to protect the mask layers 214 and the dummy gates 212 in the test region Rs1. The photoresist layer can be removed after the dielectric layer 226 is formed in the dicing region Rs2 (as shown in FIG. 10). After the dielectric layer 226 is formed in the dicing region Rs2, the mask layers 214 and the dummy gates 212 in the test region Rs1 are removed to form hollow portions H2 between two adjacent spacers 216, as shown in FIG. 12 and FIG. 13. Namely, the hollow portions H2 may be formed later than the hollow portions H1. In some embodiments, the dielectric structures 208a are removed simultaneously, such that the fins 202 are exposed by the hollow portions H2 in the test region Rs1. In some embodiments, as shown in FIG. 11A and FIG. 13, the depth of the hollow portions H2 may be smaller than the depth of the hollow portions H1, but not limited thereto.

After the hollow portions H2 are formed in the dicing region Rs2, a gate dielectric layer 228, a work function layer 230a and a metal layer 230b are sequentially formed into the hollow portions H2 to form gate structures G1. For example, each gate structure G1 is located in a corresponding hollow portion H2 and is sandwiched between the neighboring spacers 216 in the test region Rs1. As illustrated in FIG. 13, the gate structures G1 are disposed across the fins 202. In some embodiments, the work function layer 230a and the metal layer 230b may be collectively referred to as a gate 230 of the gate structures G1. In the embodiments in which the dielectric structures 208a are not removed in the formation of the hollow portions H2, the gate 230 is formed over the dielectric structures 208a.

In some embodiments, the material of the gate dielectric layer 228 may be identical to or different from the material of the dielectric layer 208. For example, the material of the gate dielectric layer 228 includes silicon oxide, silicon nitride, silicon oxynitride, or a combination thereof. In some alternative embodiments, the gate dielectric layer 228 is made of a high-k dielectric material. In some embodiments, the gate dielectric layer 228 may be formed by, for example, Molecular-Beam Deposition (MBD), ALD, PECVD, thermal oxidation, UV-ozone oxidation, a combination thereof, or the like.

As illustrated in FIG. 12 and FIG. 13, the work function layer 230a is formed on the gate dielectric layer 228. In some embodiments, the material of the work function layer 230a includes p-type or n-type work function metals. Exemplary p-type work function metals include TiN, TaN, Ru, Mo, Al, WN, ZrSi₂, MoSi₂, TaSi₂, NiSi₂, WN, other suitable p-type work function materials, or combinations thereof. On the other hand, exemplary n-type work function metals include Ti, Ag, TaAl, TaAlC, TiAlN, TaC, TaCN, TaSiN, Mn, Zr, other suitable n-type work function materials, or combinations thereof. In some embodiments, the work function layer 230a may be formed by, for example, CVD, PECVD, ALD, Remote Plasma Atomic Layer Deposition (RPALD), Plasma-Enhanced Atomic Layer Deposition (PEALD), MBD, or the like. In some embodiments, the work function layer 230a may serve the purpose of adjusting threshold voltage (Vt) of the active device 20.

The metal layer 230b is formed on the work function layer 230a. In some embodiments, the material of the metal layer 230b may include tungsten, cobalt, or the like. In some embodiments, the metal layer 230b is formed through CVD. In some embodiments, a barrier layer (not shown) may exist between the metal layer 230b and the work function layer 230a.

During the formation of the gate dielectric layer 228, the work function layer 230a and the metal layer 230b, excessive portions of these layers may be formed outside of the hollow portions H2. For example, excessive portions of these layers are formed on the etch stop layer 222 and the interlayer dielectric layer 224. As such, a planarization process, such as a CMP process, may be performed to remove excessive portions of these layers to render the structure illustrated in FIG. 12 and FIG. 13. As illustrated in FIG. 13, the gate dielectric layer 228 and the work function layer 230a have U-shaped cross-sectional views. The steps illustrated in FIG. 12 and FIG. 13 is commonly referred to as a “metal gate replacement process.”

Although FIG. 3 to FIG. 13 only illustrate the elements and/or layers in the scribe line region Rs, it should be understood that other regions (e.g., the chip region Rc and/or the seal ring region Rr) of the semiconductor structure can also include the same or similar elements and/or layers. In addition, after the step of FIG. 13, additional processes (such as the middle end of line (MEOL) and/or the back end of line (BEOL) processes) may be included.

Alternatively, although not shown, the plurality of dummy gate structures 210 in the test region Rs1 and the dicing region Rs2 can be removed and replaced with the gate structures G1 concurrently, and then the gate structures G1 in the dicing region Rs2 can then be replaced with the replacement dielectric patterns RDP to avoid wafer arcing defects caused by plasma dicing to the metal gate.

As shown in FIG. 11A and FIG. 13, the semiconductor structure 1 includes a scribe line region Rs that includes a test region Rs1 and a dicing region Rs2 adjacent to the test region Rs1. The test region Rs1 includes an active element 20. The dicing region Rs2 includes at least one layer having a plurality of patterns in the dicing region Rs2. For example, the at least one layer includes an insulator layer, and the plurality of patterns of the insulator layer include a plurality of shallow trench isolation patterns (e.g., the plurality of insulators 206 shown in FIG. 10). For example, the at least one layer includes an epitaxial layer doped with a conductive dopant, and the plurality of patterns of the epitaxial layer include a plurality of strained material structures 220 protruding out of gaps between a plurality of shallow trench isolation patterns (e.g., the plurality of insulators 206 shown in FIG. 10). For example, the at least one layer includes a dielectric layer 226, and the plurality of patterns of the dielectric layer 226 include a plurality of replacement dielectric patterns RDP disposed on a plurality of shallow trench isolation patterns (e.g., the plurality of insulators 206 shown in FIG. 10), wherein an extension direction (e.g., the second direction D2) of the plurality of replacement dielectric patterns RDP is intersected with an extension direction (e.g., the first direction D1) of the plurality of shallow trench isolation patterns (e.g., the plurality of insulators 206 shown in FIG. 10).

As shown in FIG. 10 and FIG. 11A, the semiconductor structure 1 includes a substrate 200, a plurality of insulators 206, a plurality of strained material structures 220 and a replacement dielectric pattern RDP. The plurality of insulators 206 are disposed on the substrate 200. The plurality of strained material structures 220 are disposed on the substrate 200 and separated from each other by the plurality of insulators 206. The replacement dielectric pattern RDP is disposed on the plurality of insulators 206, wherein an extension direction (e.g., the second direction D2) of the replacement dielectric pattern RDP is intersected with an extension direction (e.g., the first direction D1) of the plurality of insulators 206. The replacement dielectric pattern RDP is, for example, located in a dicing region Rs2 of the semiconductor structure 1. In some embodiments, as shown in FIG. 11A, a bottom surface of the replacement dielectric pattern RDP is lower than a bottom surface of one of the plurality of strained material structures 220. In some embodiments, as shown in FIG. 10, one of the plurality of insulators 206 has a first thickness TH1 where it overlaps the replacement dielectric pattern RDP and a second thickness TH2 greater than the first thickness TH1 where it does not overlap the replacement dielectric pattern RDP. In some embodiments, as shown in FIG. 11A, the substrate 200 has a third thickness TH3 where it overlaps the replacement dielectric pattern RDP and a fourth thickness TH4 greater than the third thickness TH3 where it does not overlap the replacement dielectric pattern RDP.

In some embodiments, as shown in FIG. 11B, the replacement dielectric pattern RDP is disposed on ends of a plurality of protrusion patterns (e.g., the recessed portions of the plurality of fins 202 or the source/drain regions 218 of the fins 202) of the substrate 200. Specifically, in the step shown in FIG. 5, the dummy gates 212 may be formed on ends of the plurality of fins 202 to prevent facet profile for epitaxial defects in the subsequent process. Therefore, after the dummy gates 212 are replaced by the replacement dielectric pattern RDP, the replacement dielectric pattern RDP is disposed on ends of the recessed portions of the plurality of fins 202 or the source/drain regions 218 of the fins 202.

Although the active device 20 in the test region Rs1 is exemplified by a fin field effect transistor, it should be understood that the active device in the test region Rs1 of the semiconductor structure in accordance with some embodiments of the disclosure is not limited to a fin field-effect transistor. For example, the active device in the test region Rs1 of the semiconductor structure in accordance with some embodiments of the disclosure can be a nanowire field-effect transistor or a nanosheet field-effect transistor, as shown in FIG. 14 to FIG. 29.

FIG. 14 is a perspective view illustrating one of various stages of a method of fabricating a semiconductor structure in accordance with some embodiments of the disclosure. Referring to FIG. 14, a substrate 100 is provided. The material of the substrate 100 may be a semiconductor material. The semiconductor material may be silicon or a group III-V semiconductor material. In the present embodiment, the material of the substrate 100 is exemplified by silicon, but the disclosure is not limited thereto.

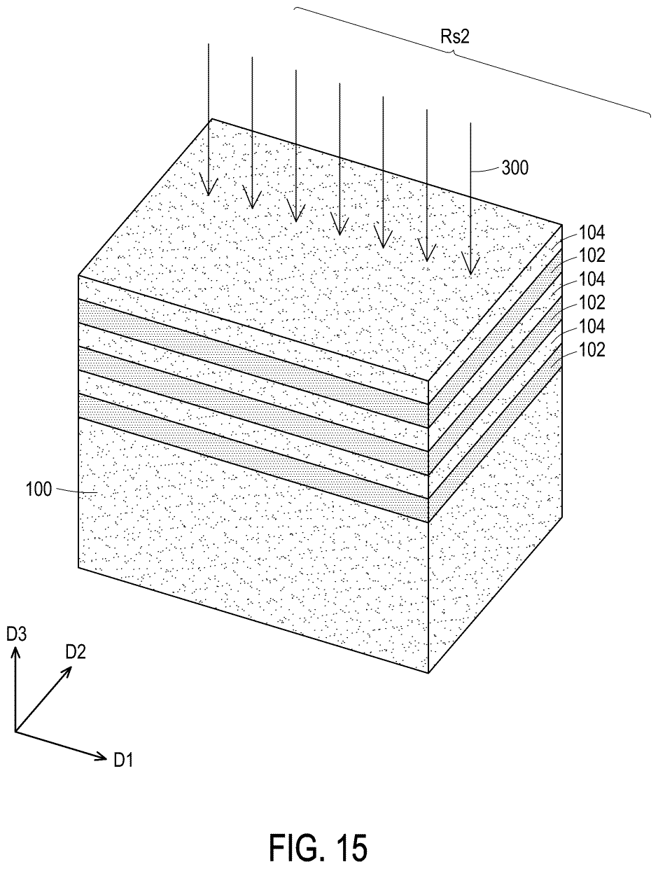

FIG. 15 is a perspective view illustrating one of various stages of a method of fabricating a semiconductor structure in accordance with some embodiments of the disclosure. Referring to FIG. 15, an ion implantation process 300 is performed on the substrate 100 to form doped material layers 102 at different depth positions of the substrate 100 and to define at least one nanowire layer 104. The at least one nanowire layer 104 and the doped material layers 102 are alternately stacked. In some embodiments, a plurality of nanowire layers 104 are defined at different depth positions of the substrate 100. The material of the doped material layers 102 may be the substrate 100 doped with the dopants. The material of the nanowire layers 104 may be the substrate 100 that is not subjected to the ion implantation process 300. The dopants used in the ion implantation process 300 may be oxygen (O), nitrogen (N), or germanium (Ge), but not limited thereto. In some embodiments, the ion implantation process 300 may be performed on the substrate 100 from deep to shallow, but the disclosure is not limited thereto. In other embodiments, the ion implantation process 300 may be performed on the substrate 100 from shallow to deep.

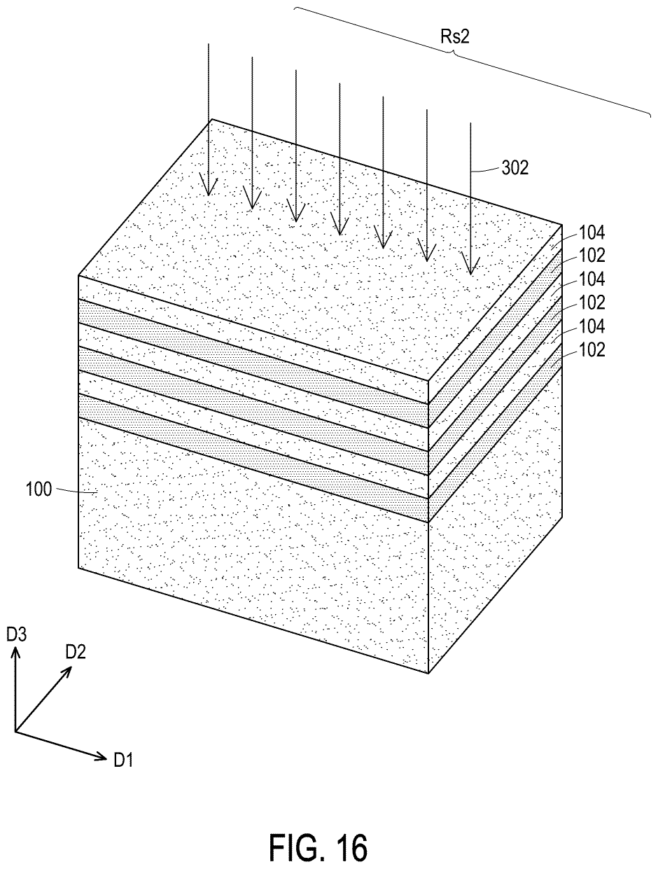

FIG. 16 is a perspective view illustrating one of various stages of a method of fabricating a semiconductor structure in accordance with some embodiments of the disclosure. Referring to FIG. 16, a thermal process 302 may be performed after forming the doped material layers 102. The thermal process 302 may cause a change in the material of the doped material layers 102. In the embodiments in which the dopants used in the ion implantation process 300 is oxygen and the material of the substrate 100 is silicon, the material of the doped material layers 102 may change from oxygen-doped silicon to silicon oxide after performing the thermal process 302. In the embodiments in which the dopants used in the ion implantation process 300 is nitrogen and the material of the substrate 100 is silicon, the material of the doped material layers 102 may change from nitrogen-doped silicon to silicon nitride after performing the thermal process 302. In the embodiments in which the dopants used in the ion implantation process 300 is germanium and the material of the substrate 100 is silicon, the material of the doped material layers 102 may change from germanium-doped silicon to silicon germanium after performing the thermal process 302. In some embodiments, the thermal process 302 may be omitted.

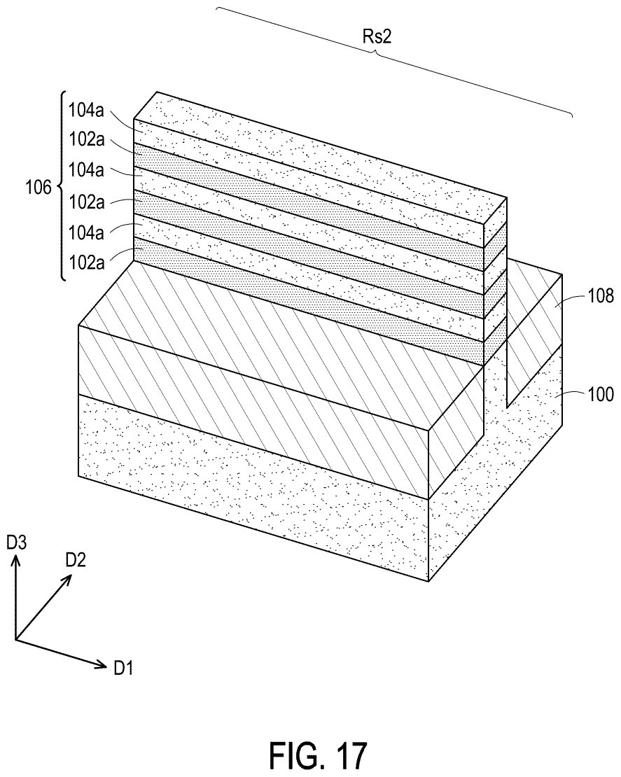

FIG. 17 is a perspective view illustrating one of various stages of a method of fabricating a semiconductor structure in accordance with some embodiments of the disclosure. Referring to FIG. 17, a patterning process is performed on the nanowire layers 104 and the doped material layers 102 to form nanowires 104a and doped layers 102a. The nanowires 104a and the doped layers 102a are alternately stacked to form a stack structure 106. The patterning process performed on the nanowire layers 104 and the doped material layers 102 is, for example, a combination of a lithography process and an etching process. In addition, a plurality of insulators 108 may be formed on the substrate 100 on two sides of the stack structure 106. The material and forming method of the plurality of insulators 108 can refer to the relevant descriptions of the insulators 206, and the repetition will be omitted herein.

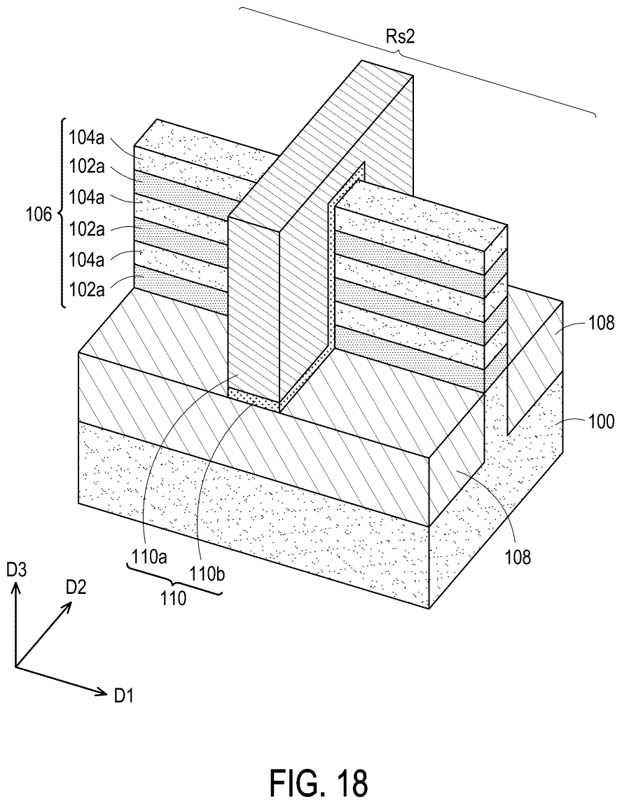

FIG. 18 is a perspective view illustrating one of various stages of a method of fabricating a semiconductor structure in accordance with some embodiments of the disclosure. Referring to FIG. 18, a dummy gate structure 110 across the stack structure 106 is formed. An extending direction (e.g., the second direction D2) of the dummy gate structure 110 may intersect an extending direction (e.g., the first direction D1) of the stack structure 106. For example, the extending direction of the dummy gate structure 110 may be perpendicular to the extending direction of the stack structure 106. The dummy gate structure 110 includes, for example, a dummy gate 110a and a dielectric layer 110b, the dielectric layer 110b may be located between the dummy gate 110a and the stack structure 106 and between the dummy gate 110a and the insulators 108. The material and forming method of the dummy gate 110a and the dielectric layer 110b can refer to the relevant descriptions of the dummy gate 212 and the dielectric structure 208a, and the repetition will be omitted herein.

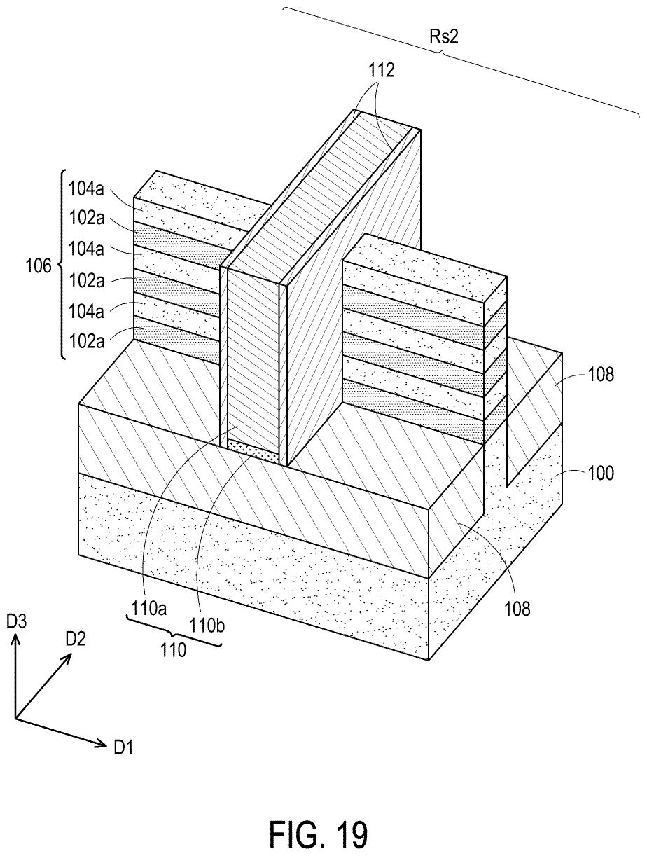

FIG. 19 is a perspective view illustrating one of various stages of a method of fabricating a semiconductor structure in accordance with some embodiments of the disclosure. Referring to FIG. 19, spacers 112 located on sidewalls of the dummy gate structure 110 are formed. The spacers 112 and the dummy gate structure 106 may have the same extending direction. The material and forming method of the spacers 112 can refer to the relevant descriptions of the spacers 216, and the repetition will be omitted herein.

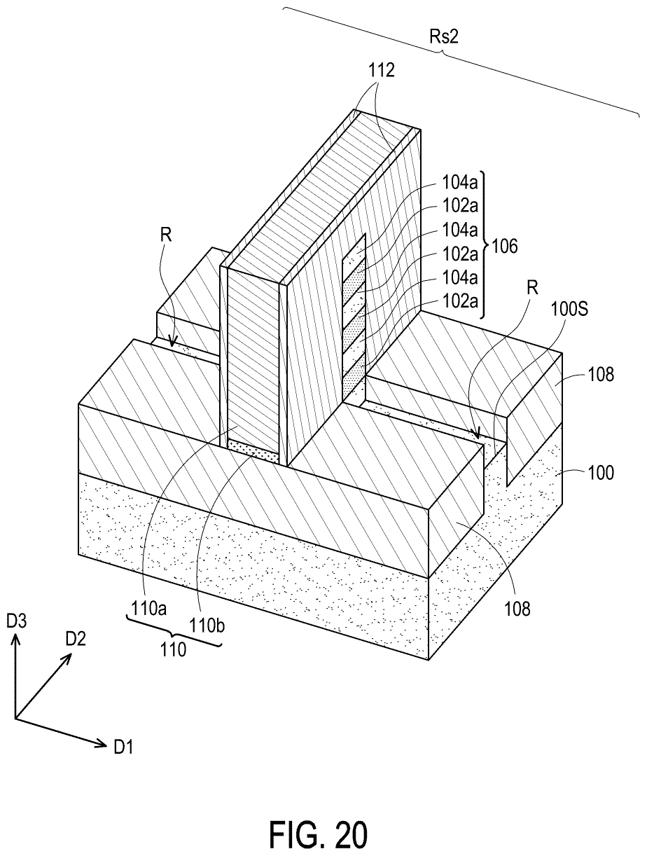

FIG. 20 is a perspective view illustrating one of various stages of a method of fabricating a semiconductor structure in accordance with some embodiments of the disclosure. Referring to FIG. 20, a portion of the stack structure 106 on the two sides of the dummy gate structure 110 is removed. For example, the stack structure 106 exposed by the dummy gate structure 110 and the spacers 112 is removed. The portion of the stack structure 106 may be removed by, for example, wet etching, dry etching, or a combination thereof. In some embodiments, the top surface 100S of substrate 100 may be recessed during the removal of the portion of the stack structure 106 to form recessed portions R, but the disclosure is not limited thereto.

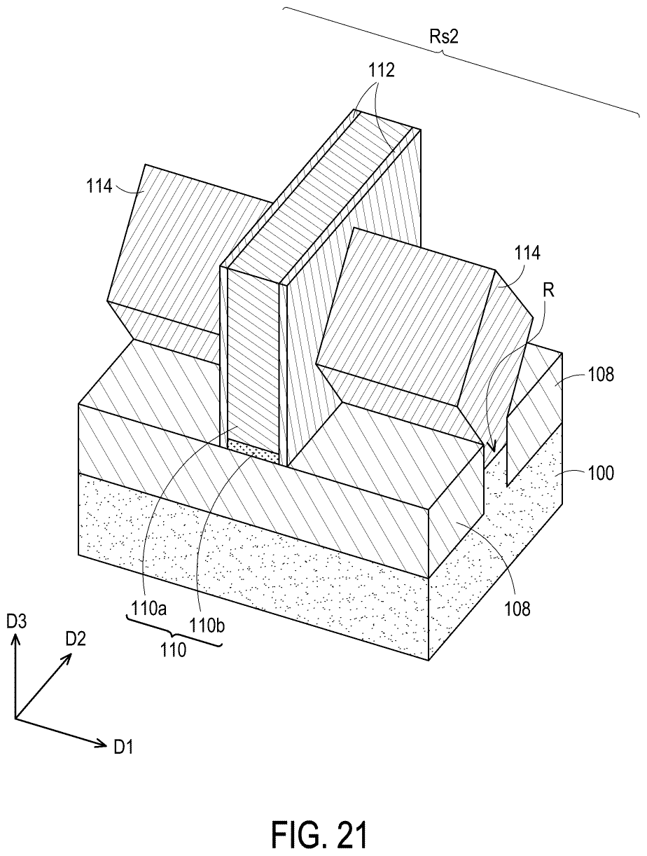

FIG. 21 is a perspective view illustrating one of various stages of a method of fabricating a semiconductor structure in accordance with some embodiments of the disclosure. Referring to FIG. 21, two strained material structures 114 (or referred to as “source/drain structures”) may be formed on two sides of the dummy gate structure 110. The detail of the strained material structures 114 can refer to the relevant descriptions of the strained material structures 220, and the repetition will be omitted herein.

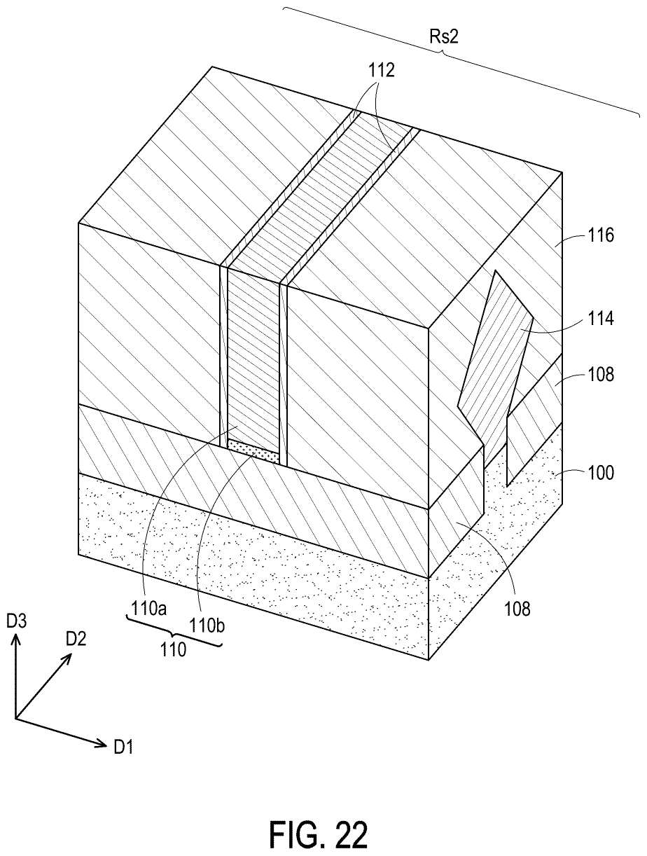

FIG. 22 is a perspective view illustrating one of various stages of a method of fabricating a semiconductor structure in accordance with some embodiments of the disclosure. Referring to FIG. 22, an interlayer dielectric (ILD) layer 116 may be formed over the dummy gate structure 110, the spacers 112, the strained material structures 114 and the plurality of insulators 108. The detail of the interlayer dielectric layer 116 can refer to the relevant descriptions of the interlayer dielectric layer 224, and the repetition will be omitted herein.

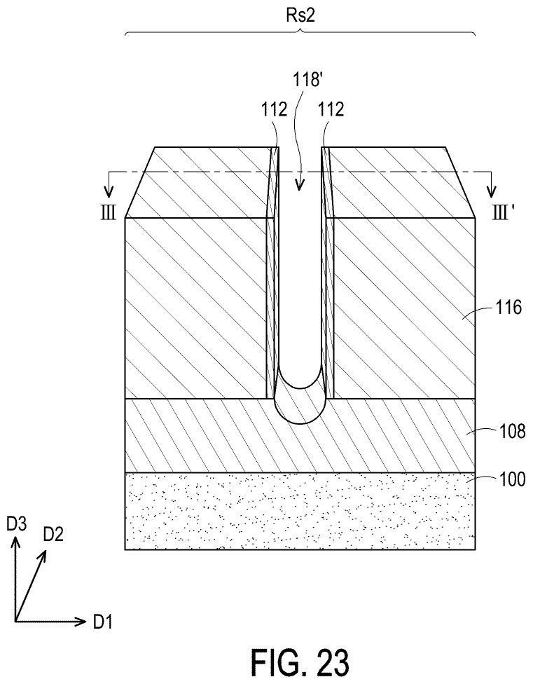

FIG. 23 is a perspective view illustrating one of various stages of a method of fabricating a semiconductor structure in accordance with some embodiments of the disclosure. Referring to FIG. 23, the dummy gate structure 110, the stack structure 106, a portion of the insulators 108 below the dummy gate structure 110 and a portion of the substrate 100 under the dummy gate structure 110 are removed by, for example, dry etching, wet etching, or a combination thereof so as to form an opening 118 between the spacers 112.

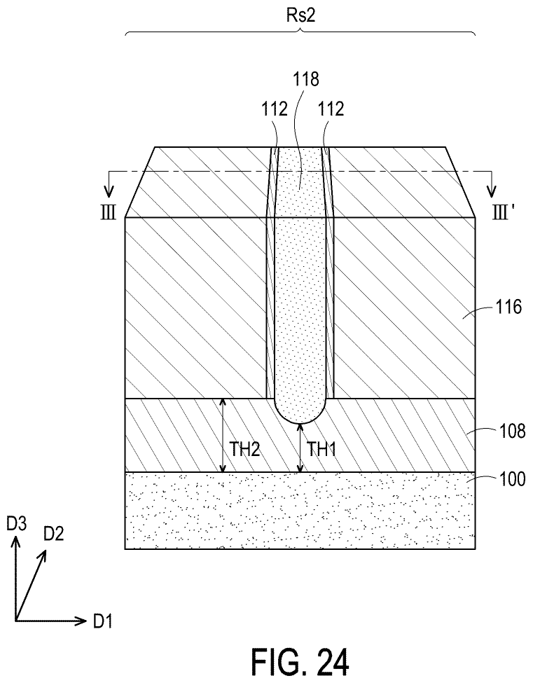

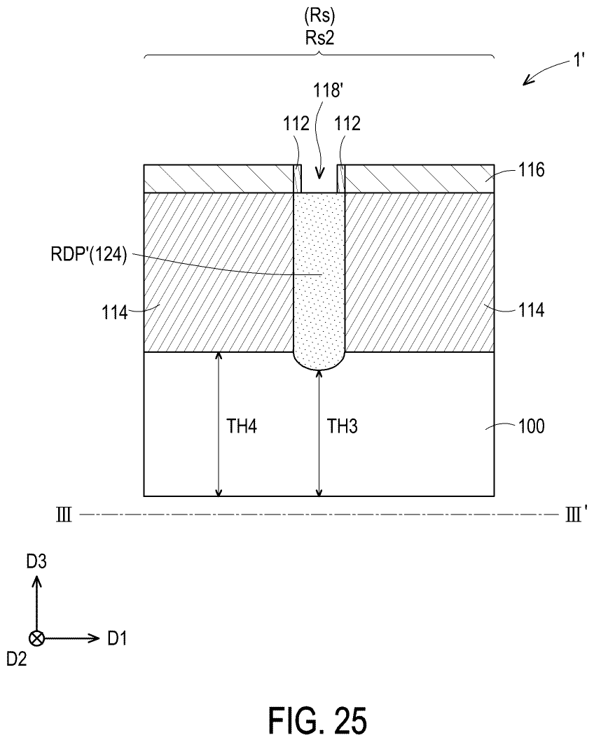

FIG. 24 is a perspective view illustrating one of various stages of a method of fabricating a semiconductor structure in accordance with some embodiments of the disclosure. FIG. 25 is a cross-sectional view taken along line III-III′ of FIG. 24. Referring to FIG. 24 and FIG. 25, a dielectric layer 124 is formed into the opening 118 to form a replacement dielectric pattern RDP′ disposed on the plurality of shallow trench isolation patterns (the insulators 108 in FIG. 24). For example, the replacement dielectric pattern RDP′ is sandwiched between the two adjacent spacers 216 in the dicing region RS2, wherein an extension direction (e.g., the second direction D2) of the replacement dielectric pattern RDP′ is intersected with an extension direction (e.g., the first direction D1) of the plurality of shallow trench isolation patterns (the insulator 108 in FIG. 24). The material and forming method of the dielectric layer 124 can refer to the relevant descriptions of the dielectric layer 226, and the repetition will be omitted herein.

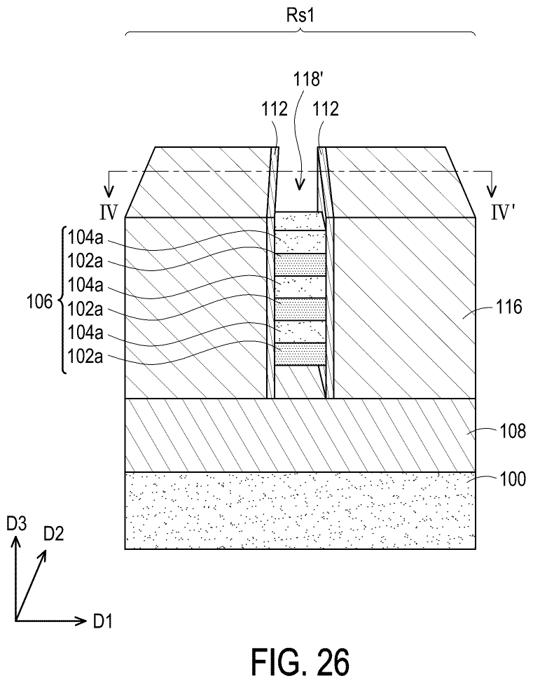

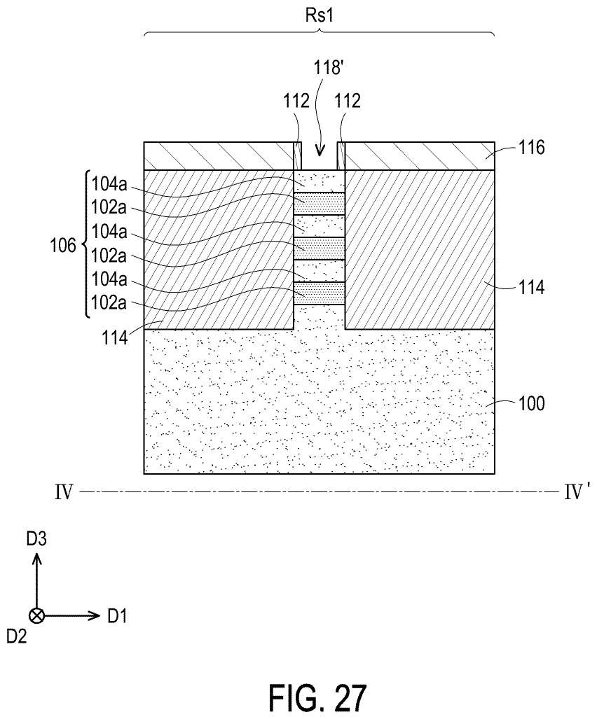

FIG. 26 is a perspective view illustrating one of various stages of a method of fabricating a semiconductor structure in accordance with some embodiments of the disclosure. FIG. 27 is a cross-sectional view taken along line IV-IV′ of FIG. 26. Referring to FIG. 26 and FIG. 27, the test region Rs1 may include a similar or the same structure shown in FIG. 22 formed according to the steps shown in FIG. 14 to FIG. 22. At least one of the layers included in both of the test region Rs1 and the dicing region Rs2 can have the same or similar patten density in the test region Rs1 and the dicing region Rs2. For example, the insulator layer including the plurality of insulators 108 (or the epitaxial layer including the plurality of strained material structures 114) can have a pattern density d1 in the test region Rs1 and a pattern density d2 in the dicing region Rs2, d1 may be equal to or approximately to d2, and both d1 and d2 follow the design rules.

In some embodiments, when the dummy gate structure 110, the stack structure 106, the portion of the insulators 108 below the dummy gate structure 110 and the portion of the substrate 100 under the dummy gate structure 110 are removed to form the opening 118 between the spacers 112 (as shown in FIG. 23), a photoresist layer (not shown) is formed in the test region Rs1 to protect the dummy gate structure 110 in the test region Rs1. The photoresist layer can be removed after the dielectric layer 118 is formed in the dicing region Rs2 (as shown in FIG. 24 or FIG. 25). After the dielectric layer 118 is formed in the dicing region Rs2, the dummy gate structure 110 is removed to expose the nanowires 104a and the doped layers 102a. Thereby, an opening 118′ may be formed between the spacers 112, as shown in FIG. 26 and FIG. 27. Namely, the opening 118′ may be formed later than the opening 118. In some embodiments, as shown in FIG. 23 and FIG. 26, the depth of the opening 118′ may be smaller than the depth of the opening 118, but not limited thereto.

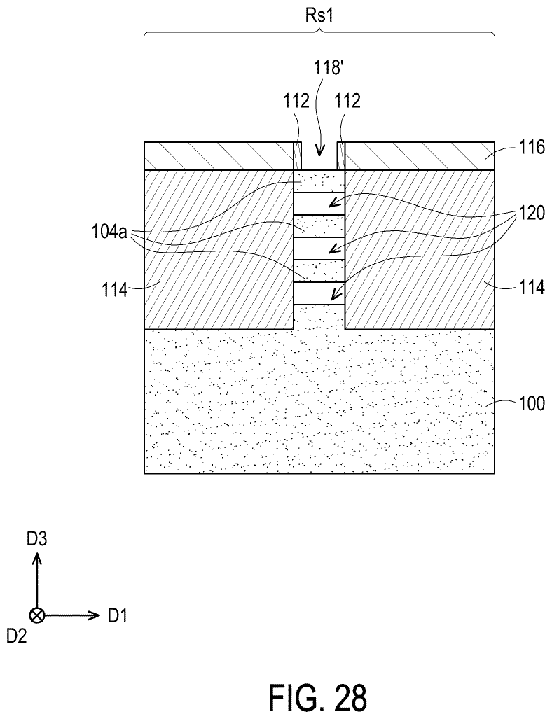

FIG. 28 is a cross-sectional view illustrating one of various stages of a method of fabricating a semiconductor structure in accordance with some embodiments of the disclosure. Referring to FIG. 28, the exposed doped layers 102a are removed to form openings 120. The step of removing the exposed doped layers 102a may be wet etching. In some embodiments, the dopants used in the ion implantation process 300 of FIG. 15 may be oxygen, and an etchant used in the wet etching may be a hydrofluoric acid (HF) or a buffered oxide etchant (BOE). In embodiments in which the material of the doped layers 102a is oxygen-doped silicon or silicon oxide, the doped layers 102a may be removed by the HF or the BOE. In some embodiments, the dopants used in the ion implantation process 300 of FIG. 15 may be nitrogen, and an etchant used in the wet etching may be a phosphoric acid. In embodiments in which the material of the doped layers 102a is nitrogen-doped silicon or silicon nitride, the doped layers 102a may be removed by the phosphoric acid. In some embodiments, the dopants used in the ion implantation process 300 of FIG. 15 may be germanium, and an etchant used in the wet etching may be a hydrochloric acid or a mixture of HF, H₂O₂, and CH₃COOH. In embodiments in which the material of the doped layers 102a is germanium-doped silicon or silicon germanium, the doped layers 102a may be removed by the hydrochloric acid or the mixture of HF, H₂O₂, and CH₃COOH.

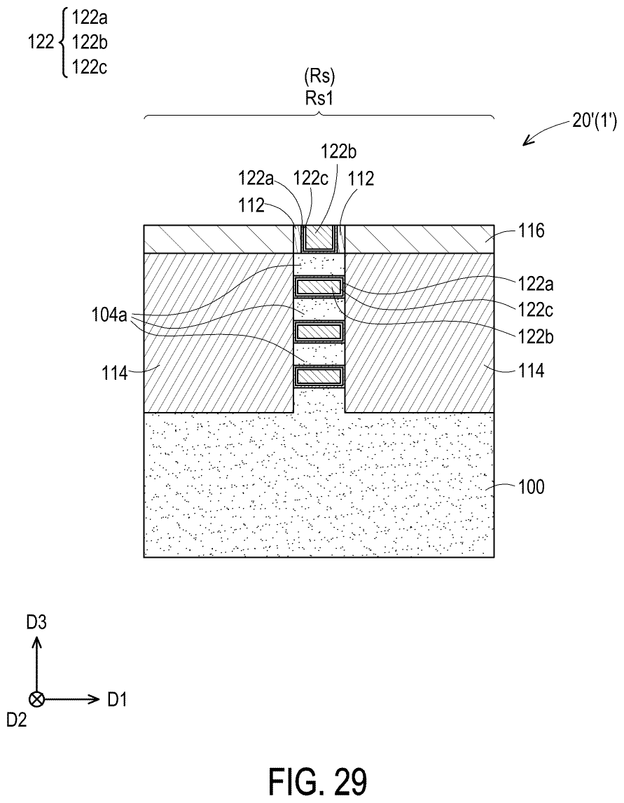

FIG. 29 is a cross-sectional view illustrating one of various stages of a method of fabricating a semiconductor structure in accordance with some embodiments of the disclosure. Referring to FIG. 29, a gate structure 122 is formed in the openings 120. Moreover, the gate structure 122 may be further formed in the opening 118′. Thereby, the gate structure 122 can surround the nanowires 104a. The gate structure 122 may include a gate dielectric layer 122a and a metal layer 122b. The gate dielectric layer 122a surrounds each nanowire 104a. The gate dielectric layer 122a may be a gate dielectric layer or a stack of gate dielectric layers (e.g., a stack of a high-k dielectric layer and an interface layer). The metal layer 122b is located on the gate dielectric layer 122a and surrounds each nanowire 104a. Furthermore, the gate structure 122 may further include a work function layer 122c. The work function layer 122c is located between the gate dielectric layer 122a and the metal layer 122b. The method of forming the gate structure 122 may include the following steps, but the invention is not limited thereto. A gate dielectric material (not shown), a work function material layer (not shown), and a metal material layer (not shown) are sequentially formed in the opening 118′ and the opening 120. A portion of the metal material layer, a portion of the work function material layer, and a portion of the gate dielectric material are removed to expose the top of the interlayer dielectric layer 116 and the top of the spacers 112 and to form the metal layer 122b, the work function layer 122c, and the gate dielectric layer 122a. The material and forming method of the gate structure 122 can refer to the relevant descriptions of the gate structures G1, and the repetition will be omitted herein.

Although FIG. 14 to FIG. 29 only illustrate the elements and/or layers in the scribe line region Rs, it should be understood that other regions (e.g., the chip region Rc and/or the seal ring region Rr) of the semiconductor structure can also include the same or similar elements and/or layers. In addition, after the step of FIG. 29, additional processes (such as the middle end of line (MEOL) and/or the back end of line (BEOL) processes) may be included.

Alternatively, although not shown, the plurality of dummy gate structures 110 in the test region Rs1 and the dicing region Rs2 can be removed concurrently to form the gate structures 122 in FIG. 29, and then the gate structure 122 and the nanowires 104a in the dicing region Rs2 can then be removed to form the replacement dielectric patterns RDP′ so as to avoid wafer arcing defects caused by plasma dicing to the metal gate.

As shown in FIG. 24, FIG. 25 and FIG. 29, the semiconductor structure 1′ includes a scribe line region Rs that includes a test region Rs1 and a dicing region Rs2 adjacent to the test region Rs1. The test region Rs1 includes an active element 20′. The dicing region Rs2 includes at least one layer having a plurality of patterns in the dicing region Rs2. For example, the at least one layer includes an insulator layer, and the plurality of patterns of the insulator layer include a plurality of shallow trench isolation patterns (e.g., the insulators 108 shown in FIG. 23). For example, the at least one layer includes an epitaxial layer doped with a conductive dopant, and the plurality of patterns of the epitaxial layer include a plurality of strained material structures 114 protruding out of gaps between a plurality of shallow trench isolation patterns (e.g., the insulators 108 shown in FIG. 23). For example, the at least one layer includes a dielectric layer 124, and the plurality of patterns of the dielectric layer 124 include a plurality of replacement dielectric patterns RDP′ (only one replacement dielectric pattern RDP′ is shown in FIG. 25) disposed on a plurality of shallow trench isolation patterns (e.g., the insulators 108 shown in FIG. 23), wherein an extension direction (e.g., the second direction D2) of the plurality of replacement dielectric patterns RDP′ is intersected with an extension direction (e.g., the first direction D1) of the plurality of shallow trench isolation patterns (e.g., the insulators 108 shown in FIG. 23).

As shown in FIG. 24 and FIG. 25, the semiconductor structure 1′ includes a substrate 100, a plurality of insulators 108, a plurality of strained material structures 114 and a replacement dielectric pattern RDP′. The plurality of insulators 108 are disposed on the substrate 100. The plurality of strained material structures 114 are disposed on the substrate 100 and separated from each other by the plurality of insulators 108. The replacement dielectric pattern RDP′ is disposed on the plurality of insulators 108, wherein an extension direction (e.g., the second direction D2) of the replacement dielectric pattern RDP′ is intersected with an extension direction (e.g., the first direction D1) of the plurality of insulators 108. The replacement dielectric pattern RDP′ is, for example, located in a dicing region Rs2 of the semiconductor structure 1′. In some embodiments, as shown in FIG. 25, a bottom surface of the replacement dielectric pattern RDP′ is lower than a bottom surface of one of the plurality of strained material structures 114. In some embodiments, as shown in FIG. 24, one of the plurality of insulators 108 has a first thickness TH1 where it overlaps the replacement dielectric pattern RDP′ and a second thickness TH2 greater than the first thickness TH1 where it does not overlap the replacement dielectric pattern RDP′. In some embodiments, as shown in FIG. 25, the substrate 100 has a third thickness TH3 where it overlaps the replacement dielectric pattern RDP′ and a fourth thickness TH4 greater than the third thickness TH3 where it does not overlap the replacement dielectric pattern RDP′.

In some embodiments, although not shown, the replacement dielectric pattern RDP′ is disposed on ends of a plurality of protrusion patterns (e.g., the recessed portions of the plurality of fins or the source/drain regions of the fins) of the substrate 100. Specifically, in the step shown in FIG. 20, the dummy gate 110a may be formed on ends of the protrusion pattern of the substrate 100 to prevent facet profile for epitaxial defects in the subsequent process. Therefore, after the dummy gate 110a is replaced by the replacement dielectric pattern RDP′, the replacement dielectric pattern RDP′ is disposed on ends of the recessed portions of the plurality of fins or the source/drain regions of the fins.

Although the active device 20′ in the test region Rs1 shown in FIG. 29 is exemplified by a nanowire field-effect transistor, it should be understood that the active device in the test region Rs1 of the semiconductor structure in accordance with some embodiments of the disclosure is not limited to a nanowire field-effect transistor. For example, the active device in the test region Rs1 of the semiconductor structure in accordance with some embodiments of the disclosure can be a nanosheet field-effect transistor.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor structure includes a scribe line region including a test region and a dicing region adjacent to the test region. The test region includes an active element. The dicing region includes at least one layer having a plurality of patterns. In some embodiments, the at least one layer includes an insulator layer, and the plurality of patterns of the insulator layer include a plurality of shallow trench isolation patterns. In some embodiments, the insulator layer is disposed on a substrate having a plurality of protrusion patterns, and the plurality of shallow trench isolation patterns are separated by the plurality of protrusion patterns. In some embodiments, the at least one layer includes an epitaxial layer doped with a conductive dopant, and the plurality of patterns of the epitaxial layer include a plurality of strained material structures protruding out of gaps between a plurality of shallow trench isolation patterns. In some embodiments, the at least one layer includes a dielectric layer, and the plurality of patterns of the dielectric layer include a plurality of replacement dielectric patterns disposed on a plurality of shallow trench isolation patterns, wherein an extension direction of the plurality of replacement dielectric patterns is intersected with an extension direction of the plurality of shallow trench isolation patterns. In some embodiments, the at least one layer is also located in the test region, and the at least one layer has a similar or the same pattern density in the dicing region and the test region. In some embodiments, the dicing region is a metal-free region. In some embodiments, the active element includes a fin field-effect transistor, a nanowire field-effect transistor or a nanosheet field-effect transistor.

According to some embodiments, a semiconductor structure includes a substrate, a plurality of insulators, a plurality of strained material structures and a replacement dielectric pattern. The plurality of insulators are disposed on the substrate. The plurality of strained material structures are disposed on the substrate and separated from each other by the plurality of insulators. The replacement dielectric pattern is disposed on the plurality of insulators, wherein an extension direction of the replacement dielectric pattern is intersected with an extension direction of the plurality of insulators. In some embodiments, the replacement dielectric pattern is located in a dicing region of the semiconductor structure. In some embodiments, a bottom surface of the replacement dielectric pattern is lower than a bottom surface of one of the plurality of strained material structures. In some embodiments, one of the plurality of insulators has a first thickness where it overlaps the replacement dielectric pattern and a second thickness greater than the first thickness where it does not overlap the replacement dielectric pattern. In some embodiments, the substrate has a third thickness where it overlaps the replacement dielectric pattern and a fourth thickness greater than the third thickness where it does not overlap the replacement dielectric pattern. In some embodiments, the replacement dielectric pattern is disposed on ends of the plurality of insulators.

According to some embodiments, a manufacturing method of a semiconductor structure includes forming an active element in a test region of a scribe line region and forming at least one layer having a plurality of patterns in a dicing region of the scribe line region, wherein the dicing region is adjacent to the test region. In some embodiments, the at least one layer includes an insulator layer, and the plurality of patterns of the insulator layer include a plurality of shallow trench isolation patterns. In some embodiments, the insulator layer is disposed on a substrate having a plurality of protrusion patterns, and the plurality of shallow trench isolation patterns are separated by the plurality of protrusion patterns. In some embodiments, the at least one layer includes an epitaxial layer doped with a conductive dopant, and the plurality of patterns of the epitaxial layer include a plurality of strained material structures protruding out of gaps between a plurality of shallow trench isolation patterns. In some embodiments, the at least one layer includes a dielectric layer, and the plurality of patterns of the dielectric layer include a plurality of replacement dielectric patterns disposed on a plurality of shallow trench isolation patterns, wherein an extension direction of the plurality of replacement dielectric patterns is intersected with an extension direction of the plurality of shallow trench isolation patterns. In some embodiments, forming the plurality of replacement dielectric patterns includes removing a plurality of dummy gates and a portion of a substrate under the plurality of dummy gates.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a scribe line region comprising:
a test region comprising an active element; and
a dicing region adjacent to the test region and comprising at least one layer having a plurality of patterns.

2. The semiconductor structure as claimed in claim 1, wherein the at least one layer comprises an insulator layer, and the plurality of patterns of the insulator layer comprise a plurality of shallow trench isolation patterns.

3. The semiconductor structure as claimed in claim 2, wherein the insulator layer is disposed on a substrate having a plurality of protrusion patterns, and the plurality of shallow trench isolation patterns are separated by the plurality of protrusion patterns.

4. The semiconductor structure as claimed in claim 1, wherein the at least one layer comprises an epitaxial layer doped with a conductive dopant, and the plurality of patterns of the epitaxial layer comprise a plurality of strained material structures protruding out of gaps between a plurality of shallow trench isolation patterns.

5. The semiconductor structure as claimed in claim 1, wherein the at least one layer comprises a dielectric layer, and the plurality of patterns of the dielectric layer comprise a plurality of replacement dielectric patterns disposed on a plurality of shallow trench isolation patterns, wherein an extension direction of the plurality of replacement dielectric patterns is intersected with an extension direction of the plurality of shallow trench isolation patterns.

6. The semiconductor structure as claimed in claim 1, wherein the at least one layer is also located in the test region, and the at least one layer has a similar or the same pattern density in the dicing region and the test region.

7. The semiconductor structure as claimed in claim 1, wherein the dicing region is a metal-free region.

8. The semiconductor structure as claimed in claim 1, wherein the active element comprises a fin field-effect transistor, a nanowire field-effect transistor or a nanosheet field-effect transistor.

9. A semiconductor structure, comprising:
a substrate;
a plurality of insulators disposed on the substrate;
a plurality of strained material structures disposed on the substrate and separated from each other by the plurality of insulators; and
a replacement dielectric pattern disposed on the plurality of insulators, wherein an extension direction of the replacement dielectric pattern is intersected with an extension direction of the plurality of insulators.

10. The semiconductor structure as claimed in claim 9, wherein the replacement dielectric pattern is located in a dicing region of the semiconductor structure.

11. The semiconductor structure as claimed in claim 9, wherein a bottom surface of the replacement dielectric pattern is lower than a bottom surface of one of the plurality of strained material structures.

12. The semiconductor structure as claimed in claim 9, wherein one of the plurality of insulators has a first thickness where it overlaps the replacement dielectric pattern and a second thickness greater than the first thickness where it does not overlap the replacement dielectric pattern.

13. The semiconductor structure as claimed in claim 9, wherein the substrate has a third thickness where it overlaps the replacement dielectric pattern and a fourth thickness greater than the third thickness where it does not overlap the replacement dielectric pattern.

14. The semiconductor structure as claimed in claim 9, wherein the replacement dielectric pattern is disposed on ends of a plurality of protrusion patterns of the substrate.

15. A manufacturing method of a semiconductor structure, comprising:
forming an active element in a test region of a scribe line region; and
forming at least one layer having a plurality of patterns in a dicing region of the scribe line region, wherein the dicing region is adjacent to the test region.

16. The manufacturing method of the semiconductor structure as claimed in claim 15, wherein the at least one layer comprises an insulator layer, and the plurality of patterns of the insulator layer comprise a plurality of shallow trench isolation patterns.

17. The manufacturing method of the semiconductor structure as claimed in claim 16, wherein the insulator layer is disposed on a substrate having a plurality of protrusion patterns, and the plurality of shallow trench isolation patterns are separated by the plurality of protrusion patterns.

18. The manufacturing method of the semiconductor structure as claimed in claim 15, wherein the at least one layer comprises an epitaxial layer doped with a conductive dopant, and the plurality of patterns of the epitaxial layer comprise a plurality of strained material structures protruding out of gaps between a plurality of shallow trench isolation patterns.

19. The manufacturing method of the semiconductor structure as claimed in claim 15, wherein the at least one layer comprises a dielectric layer, and the plurality of patterns of the dielectric layer comprise a plurality of replacement dielectric patterns disposed on a plurality of shallow trench isolation patterns, wherein an extension direction of the plurality of replacement dielectric patterns is intersected with an extension direction of the plurality of shallow trench isolation patterns.

20. The manufacturing method of the semiconductor structure as claimed in claim 19, wherein forming the plurality of replacement dielectric patterns comprises removing a plurality of dummy gates and a portion of a substrate under the plurality of dummy gates.
